(19) United States
(12) Patent Application Publication
(10) Pub. No.: US 2025/0372131 A1
(43) Pub. Date: Dec. 4, 2025

(54) THRESHOLD VOLTAGE COMPENSATION FOR A MEMORY SYSTEM SENSE AMPLIFIER

(71) Applicant: Micron Technology, Inc., Boise, ID (US)

(72) Inventors: Ferdinando Bedeschi, Biassono (MB) (IT); Umberto Di Vincenzo, Capriate San Gervasio (BG) (IT); Riccardo Muzzetto, Arcore (MB) (IT)

(21) Appl. No.: 19/190,460

(22) Filed: Apr. 25, 2025

Related U.S. Application Data
(60) Provisional application No. 63/655,981, filed on Jun. 4, 2024.

(51) Int. Cl. G11C 7/08; G11C 5/14; G11C 7/10

(52) U.S. Cl. CPC G11C 7/08; G11C 5/147; G11C 7/106

(57) ABSTRACT

Methods, systems, and devices for threshold voltage compensation for a memory system sense amplifier are described. A sense amplifier may include a first transistor comprising: a gate terminal coupled with a second digit line, a drain terminal coupled with a first digit line through a first switching component, and a source terminal coupled with a node. The sense amplifier may include a second transistor comprising a source terminal coupled with the node. The sense amplifier may include a first voltage supply configured to be coupled with the node using a third transistor during an amplification phase of a sense operation for the memory cell; and a second voltage supply configured to be coupled with the node through a fourth transistor during a compensation phase of the sense operation.

### CROSS REFERENCE

The present application for patent claims priority to U.S. Patent Application No. 63/655,981 by Bedeschi et al., entitled “THRESHOLD VOLTAGE COMPENSATION FOR A MEMORY SYSTEM SENSE AMPLIFIER,” filed Jun. 4, 2024, which is assigned to the assignee hereof, and which is expressly incorporated by reference in its entirety herein.

### TECHNICAL FIELD

The following relates to one or more systems for memory, including threshold voltage compensation for a memory system sense amplifier.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports threshold voltage compensation for a memory system sense amplifier in accordance with examples as disclosed herein.

FIG. 2 shows an example of an architecture that supports threshold voltage compensation for a memory system sense amplifier in accordance with examples as disclosed herein.

FIG. 3 shows an example of a sense amplifier that supports threshold voltage compensation in accordance with examples as disclosed herein.

FIG. 4 shows an example of a timing diagram that supports threshold voltage compensation for a memory system sense amplifier in accordance with examples as disclosed herein.

FIG. 5 shows examples of timing diagrams that support threshold voltage compensation for a memory system sense amplifier in accordance with examples as disclosed herein.

FIG. 6 shows an example of a sense amplifier that supports threshold voltage compensation in accordance with examples as disclosed herein.

FIG. 7 shows an example of a timing diagram that supports threshold voltage compensation for a memory system sense amplifier in accordance with examples as disclosed herein.

FIG. 8 shows a block diagram of a memory system that supports threshold voltage compensation for a memory system sense amplifier in accordance with examples as disclosed herein.

FIG. 9 shows a flowchart illustrating a method or methods that support threshold voltage compensation for a memory system sense amplifier in accordance with examples as disclosed herein.

### DETAILED DESCRIPTION

A memory system may use one or more sense amplifiers to sense, and in some cases, latch, data signals read from memory cells. For example, a memory system may use a sense amplifier to develop (e.g., on a node of the sense amplifier) a data signal (e.g., a voltage differential) that represents a logic state (e.g., a logic 1, a logic 0) stored by a memory cell. The sense amplifier may include a first set of transistors (e.g., n-type transistors) and a second set of transistors (e.g., p-type transistors) and each transistor may have an associated (e.g., intrinsic) threshold voltage.

To mitigate sensing issues that arise from the threshold voltages of the first set of transistors, operation of the sense amplifier may include a compensation phase that compensates for the threshold voltages of the first set of transistors. But the compensated threshold voltages (e.g., the threshold voltage of the first set of transistors) may be different than the threshold voltages of the second set of transistors (a phenomenon referred to herein as compensation mismatch), which can impact amplification of the data signal during an amplification phase of operating the sense amplifier. In some cases, the differences in the threshold voltages may render the compensation less effective and decrease the reliability of reading. Put another way, the threshold voltage of the transistors (e.g., the first set of transistors) compensated for during the compensation phase may be different than the threshold voltage of the transistors used to amplify the data signal during the amplification phase, resulting in compensation mismatch.

The techniques and designs described herein enable operation of a sense amplifier with reduced or eliminated compensation mismatch. The sense amplifier may include two voltage supplies—such as a first voltage supply (e.g., a voltage supply Vnary) and a second voltage supply (e.g., a voltage supply Vss)—coupled with the first set of transistors. The first voltage supply may be used during a compensation phase of operating the sense amplifier that compensates for the threshold voltages of the first set of transistors whereas the second voltage supply may be used during an amplification phase of operating the sense amplifier. The first voltage supply may be higher (e.g., supply a higher voltage level) than the second voltage supply to enable use of the first set of transistors (e.g., instead of the second set of transistors) to amplify the data signal during the amplification phase. Such a technique may ensure that the transistors compensated for during the compensation phase (e.g., the first set of transistors) are the same transistors that are used during the amplification phase, thus reducing or eliminating compensation mismatch.

In addition to applicability in memory systems as described herein, techniques for threshold compensation at a sense amplifier may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by increasing the reliability of sense operations, which may decrease processing or latency times, improve response times, or otherwise improve user experience, among other benefits.

In addition to applicability in memory systems as described herein, techniques for threshold compensation at a sense amplifier may be generally implemented to support increased connectivity of electronic systems. As the use of systems relying on interconnected electronic devices increases, the connectivity of these electronic devices becomes an increasingly relevant factor for the operations of the system. For example, delays associated with signals communicated between devices may become increasingly relevant as critical systems come to rely more on connectivity, as a system uses larger quantities of interconnected devices, or if the quantity and the complexity of signals communicated between devices increases. Implementing the techniques described herein may support techniques for increased connectivity in electronic systems by increasing the reliability of sense operations, among other benefits.

Features of the disclosure are illustrated and described in the context of systems and architectures. Features of the disclosure are further illustrated and described in the context of sense amplifiers, timing diagrams, device diagrams, and flowcharts.

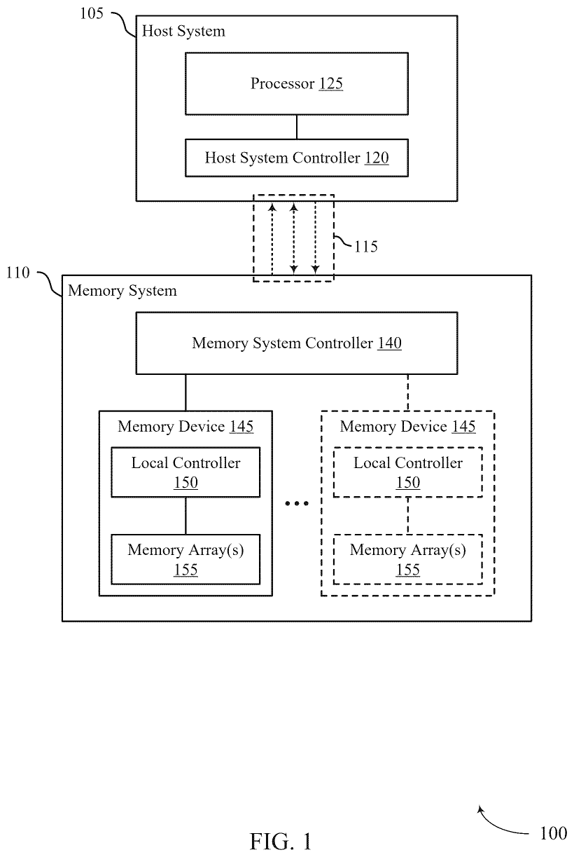

FIG. 1 illustrates an example of a system 100 that supports threshold voltage compensation for a memory system sense amplifier in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, the data stored by a memory array 155 may be sensed by a sense amplifier. For example, the logic state stored by a memory cell of a memory array 155 may be sensed by a sense amplifier using a sense operation. The sense amplifier may include a first set of transistors (e.g., n-type transistors) and a second set of transistors (e.g., p-type transistors) that have different threshold voltages. To prevent the threshold voltages of the transistors from negatively impacting the sense operation, operation of the sense amplifier may include a compensation phase that compensates for the threshold voltages of the first set of transistors. To reduce or eliminate compensation mismatch (e.g., in which the compensated threshold voltages are different than the threshold voltages that impact the data signal during amplification), the sense amplifier may be operated so that the first set of transistors (e.g., rather than the second set of transistors) is used during an amplification phase of the sense operation.

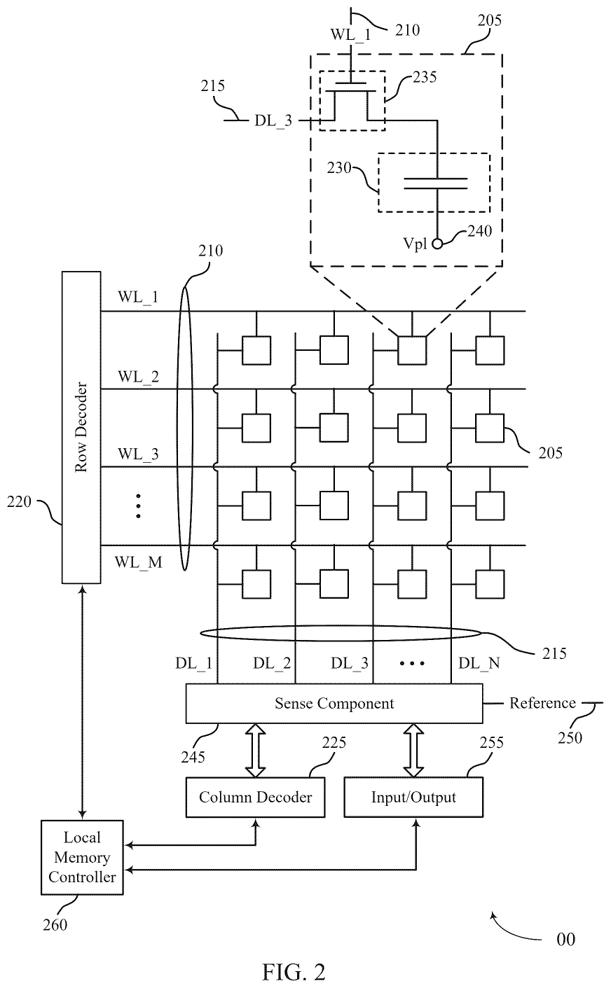

FIG. 2 illustrates an example of an architecture 200 (e.g., a memory architecture) that supports threshold voltage compensation for a memory system sense amplifier in accordance with examples as disclosed herein. The architecture 200 may be implemented in a memory system 110 or one or more components thereof (e.g., memory device 145). Aspects of the architecture 200 may be referred to as or implemented in a semiconductor component, such as a memory die.

The architecture 200 includes memory cells 205 that are programmable to store information. In some examples, a memory cell 205 may be operable to store one bit of information at a time (e.g., a logic 0 or a logic 1). In some examples, a memory cell 205 (e.g., a multi-level memory cell) may be operable to store more than one bit of information at a time (e.g., a logic 00, logic 01, logic 10, a logic 11). Memory cells 205 may be arranged in an array, such as in a memory array 155.

In the example of architecture 200, a memory cell 205 may include a storage component, such as capacitor 230, and a selection component 235 (e.g., a cell selection component, a transistor). A capacitor 230 may be a dielectric capacitor or a ferroelectric capacitor. A node of the capacitor 230 may be coupled with a voltage source 240, which may be a cell plate reference voltage, such as Vpl, or may be a ground voltage, such as Vss. A charge stored by a memory cell 205 (e.g., by a capacitor 230) may be representative of a programmed state. Other memory architectures that support the techniques described herein may implement different types or arrangements of storage components and associated circuitry (e.g., with or without a selection component).

The architecture 200 may include various arrangements of access lines, such as word lines 210 and digit lines 215. An access line may be a conductive line that is coupled with a memory cell 205, and may be used to perform access operations on the memory cell 205. Word lines 210 may be referred to as row lines, and digit lines 215 may be referred to as column lines or bit lines, among other nomenclature. Memory cells 205 may be positioned at intersections of access lines, and an intersection may be referred to as an address of a memory cell 205.

In some architectures, a word line 210 may be coupled with a gate of a selection component 235 of a memory cell 205, and may be operable to control (e.g., switch, modulate a conductivity of) the selection component 235. A digit line 215 may be operable to couple a memory cell 205 with a sense component 245. In some architectures, a memory cell 205 (e.g., a capacitor 230) may be coupled with a digit line 215 during portions of an access operation. For example, a word line 210 and a selection component 235 of a memory cell 205 may be operable to couple or isolate a capacitor 230 of the memory cell 205 with a digit line 215.

Operations such as reading and writing may be performed on memory cells 205 by activating (e.g., applying a voltage to) access lines such as a word line 210 or a digit line 215. Accessing the memory cells 205 may be controlled through a row decoder 220, or a column decoder 225, or a combination thereof. For example, a row decoder 220 may receive a row address (e.g., from a local memory controller 260) and activate a word line 210 based on a received row address, and a column decoder 225 may receive a column address and activate a digit line 215 based on a received column address. Selecting or deselecting a memory cell 205 may include activating or deactivating a selection component 235 using a word line 210. For example, a capacitor 230 may be isolated from a digit line 215 when the selection component 235 is deactivated, and the capacitor 230 may be coupled with the digit line 215 when the selection component 235 is activated.

A sense component 245 may be operable to detect a state (e.g., a charge) stored by a capacitor 230 of a memory cell 205 and determine a logic state of the memory cell 205 based on the stored state. A sense component 245 may include one or more sense amplifiers to amplify or otherwise convert a signal resulting from accessing the memory cell 205. The sense component 245 may compare a signal detected from the memory cell 205 with a reference 250 (e.g., a reference voltage). The detected logic state of the memory cell 205 may be provided as an output of the sense component 245 (e.g., via an input/output 255), and may indicate the detected logic state to another component of a memory system 110 that implements the architecture 200.

The local memory controller 260 may control the accessing of memory cells 205 through the various components (e.g., a row decoder 220, a column decoder 225, a sense component 245), and may be an example of or otherwise included in a local controller 150, or a memory system controller 140, or both. In some examples, one or more of a row decoder 220, a column decoder 225, and a sense component 245 may be co-located with or included in the local memory controller 260. The local memory controller 260 may be operable to receive commands or data from one or more different controllers (e.g., a host system controller 120, a memory system controller 140), translate the commands or the data into information that can be used by the architecture 200, initiate or control one or more operations of the architecture 200, and communicate data from the architecture 200 to a host (e.g., a host system 105) based on performing the one or more operations.

The local memory controller 260 may be operable to perform one or more access operations on one or more memory cells 205 of the architecture 200. Examples of an access operation may include a write operation, a read operation, a refresh operation, a precharge operation, or an activate operation, among others. In some examples, an access operation may be performed by or otherwise coordinated by the local memory controller 260 in response to one or more access commands (e.g., from a host system 105). The local memory controller 260 may be operable to perform other access operations not listed here or other operations related to the operating of the architecture 200 that are not directly related to accessing the memory cells 205.

To support an access operation, a local memory controller 260 may identify a target memory cell 205 on which to perform the access operation, which may be associated with identifying a target word line 210 and a target digit line 215 coupled with the target memory cell 205 (e.g., an address of the target memory cell 205). The local memory controller 260 may control activating the target word line 210 and the target digit line 215 to access the target memory cell 205. During a write operation, the local memory controller 260 may control the application of a signal (e.g., a write pulse, a write voltage) to the target digit line 215 to store a specific state (e.g., a charge, in a capacitor 230) of the memory cell 205. The signal used as part of the write operation may include one or more voltage levels applied to the target memory cell 205 (e.g., via the target digit line 215) over one or more respective durations. During a read operation, the target memory cell 205 may transfer a signal (e.g., charge, voltage) to the sense component 245 based on activating the target word line 210 and the target digit line. The local memory controller 260 may activate the sense component 245 (e.g., initiate latching a sense amplifier of the sense component 245), which may include comparing the signal transferred from the memory cell 205 to a reference (e.g., the reference 250). Based on the comparison, the sense component 245 may determine a logic state that is stored on the memory cell 205.

In some examples, a sense component 245 may be or include a sense amplifier as described herein. The sense amplifier may sense a logic state of a memory cell 205 using a sense operation that includes multiple phases. For example, during a precharge phase the sense amplifier may precharge two digit lines that are coupled with the sense amplifier. During a compensation phase, the sense amplifier may compensate for the threshold voltages of a set of transistors (e.g., n-type transistors). During a sensing phase, the sense amplifier may facilitate charge-sharing between one of the digit lines and sense amplifier so that a data signal (e.g., voltage differential) is developed at the sense amplifier. During an amplification phase, the sense amplifier may amplify (and potentially invert) the data signal using the set of transistors whose threshold voltages were compensated during the compensation phase. Thus, according to the techniques described herein, the sense amplifier may be configured and operated to support use of the same set of transistors during the compensation phase and the amplification phase, which may reduce or eliminate compensation mismatch. During a latching phase the sense amplifier may latch the data signal at the sense amplifier (e.g., for sampling by another component, for writing back to the memory cell, or both).

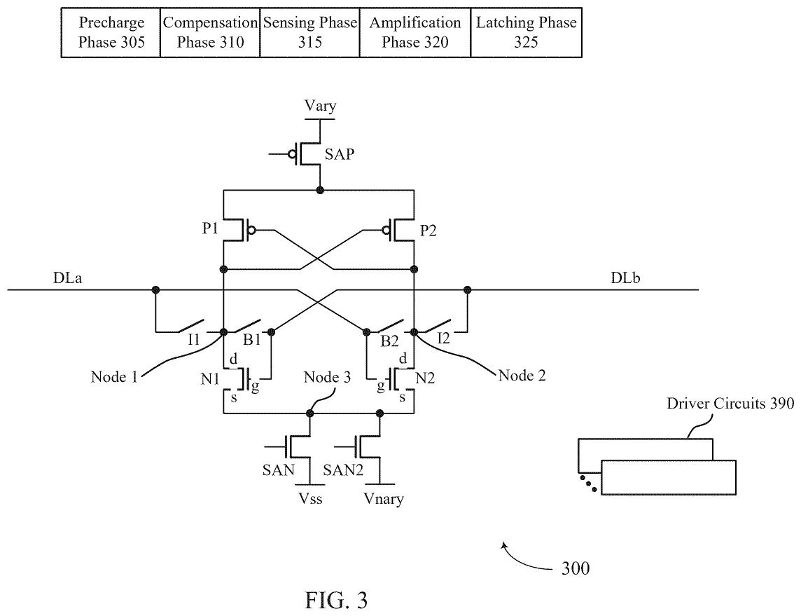

FIG. 3 shows an example of a sense amplifier 300 that supports threshold voltage compensation in accordance with examples as disclosed herein. The sense amplifier 300 may be configured to sense a logic state of a memory cell (e.g., memory cell A) coupled with digit line DLa. The sense amplifier 300 may include two voltage supplies, Vss and Vnary, that are coupled with the node 3 and that enable threshold voltage compensation for transistor N1 and transistor N2 as well as amplification of a voltage differential (e.g., representative of the logic state stored by memory cell A) by transistor N1 and transistor N2. Thus, the sense amplifier 300 may be configured and operated to support compensation of the same set of transistors (e.g., transistor N1, transistor N2) that are used for amplification, which may reduce or eliminate compensation mismatch.

The sense amplifier 300 may include transistors and switching components. A deactivated transistor or switching component may refer to a state of the transistor or switching component that does not support the flow of current between the source terminal and the drain terminal of that transistor or switching component. A deactivated transistor or switching component may be referred to as an open transistor or switching component. An activated transistor or switching component may refer to a state of the transistor or switching component that supports the flow of current between the source terminal and the drain terminal of that transistor or switching component. An activated transistor or switching component may be referred to as a closed transistor or switching component. A transistor or switching component may be configured to selectively couple two components if the transistor or switching component is capable of opening a conductive path between the components (e.g., electrically coupling the components) and closing the conductive path between the components (e.g., electrically isolating the components).

The sense amplifier 300 may include or be coupled with one or more driver circuits 390. A driver circuit 390 may be configured to apply bias voltages to one or more component(s) (e.g., word lines, transistors, switching components) to activate or deactivate the component(s). For instance, a driver circuit 390 may be configured to apply bias voltages to the gate terminal of a switching component or a transistor to activate or deactivate that switching component or transistor. Thus, one or more driver circuits 390, which may be collectively referred to as driver circuitry, may be coupled with the components of the sense amplifier 300. In some examples, the one or more driver circuits 390 may be coupled with, and controlled by, one or more controllers of the memory system that includes the sense amplifier 300.

The sense amplifier 300 may include a first set of n-type transistors, transistor N1 and transistor N2, and a second set of p-type transistors, transistor P1 and transistor P2. Transistor N1 may include a source terminal (denoted “s”) that is coupled with node 3, a drain terminal (denoted “d”) that is coupled with switching components I1 and B1, and a gate terminal (denoted “g”) that is coupled with digit line DLb. Transistor N2 may include a source terminal (denoted “s”) that is coupled with node 3, a drain terminal (denoted “d”) that is coupled with switching components I2 and B2, and a gate terminal (denoted “g”) that is coupled with digit line DLa.

The sense amplifier 300 may also include: transistor SAP (e.g., a p-type transistor), which may be configured to selectively couple voltage supply Vary with transistor P1 and transistor P2; transistor SAN (e.g., an n-type transistor), which may be configured to selectively couple voltage supply Vss with node 3 (and thus transistor N1 and transistor N2); and transistor SAN2 (e.g., an n-type transistor), which may be configured to selectively couple the voltage supply Vnary with node 3 (and thus transistor N1 and transistor N2). In some examples, the voltage level supplied by (e.g., outputted by) voltage supply Vary may be higher than the voltage supplied by Vnary, which may be higher than the voltage supplied by voltage supply Vss. For example, voltage supply Vary may supply a voltage level around 1.5 V, voltage supply Vnary may supply a voltage level around 200 mV, and voltage supply Vss may provide a ground voltage level (e.g. 0 V).

The sense amplifier 300 may also include switching components such as: switching component I1, which may be configured to selectively couple node 1 with digit line DLa and the gate terminal of transistor N2; switching component B1, which may be configured to selectively couple node 1 with digit line DLb and the gate terminal of transistor N1; switching component I2, which may be configured to selectively couple node 2 with digit line DLb and the gate terminal of transistor N1; and switching component B2, which may be configured to selectively couple node 2 with digit line DLa and the gate terminal of transistor N2. In some examples, the switching components may be transistors.

The transistors of the sense amplifier 300 may have respective intrinsic threshold voltages that can impact the operation of the sense amplifier 300. For example, transistor N1 and transistor N2 may have respective intrinsic threshold voltages and transistor P1 and P2 may have respective intrinsic threshold voltages.

During the compensation phase 310, the threshold voltages of transistor N1 and transistor N2 may be compensated. Unlike other techniques, which may use voltage supply Vss for the compensation phase (and omit voltage supply Vnary), the sense amplifier 300 may use voltage supply Vnary for the compensation phase. Use of voltage supply Vnary, which outputs a higher voltage level than voltage supply Vss, may allow the sense amplifier 300 to use transistor N1 and transistor N2 for amplification during the amplification phase 320. So, during the amplification phase 320, transistor N1 and transistor N2 may be used to amplify the voltage differential (e.g., between digit line DLa and digit line DLb) representative of the logic state stored by memory cell A. Unlike other techniques, which may use voltage supply Vary for the amplification phase, the sense amplifier 300 may use voltage supply Vss for the amplification phase so that the transistors used for amplification (e.g., transistor N1 and transistor N2) are the same transistors whose threshold voltages were compensated during the compensation phase, which may reduce or eliminate compensation mismatch.

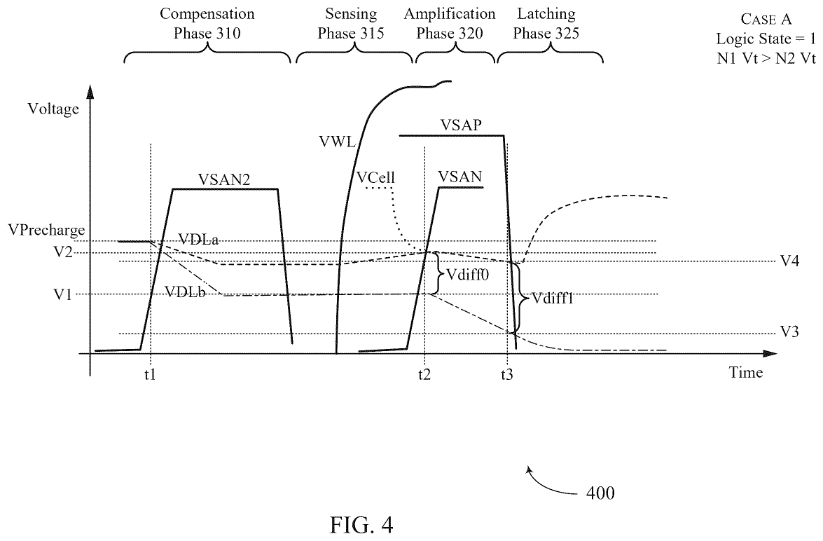

A high-level description of the operation the sense amplifier 300 is briefly described. Additional details related to the operation of the sense amplifier are further described with reference to FIG. 4 and subsequent figures.

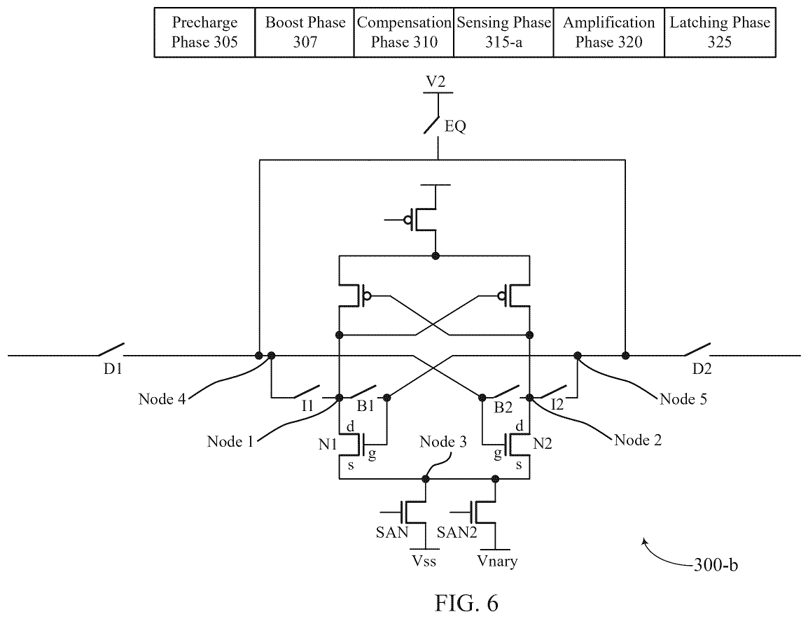

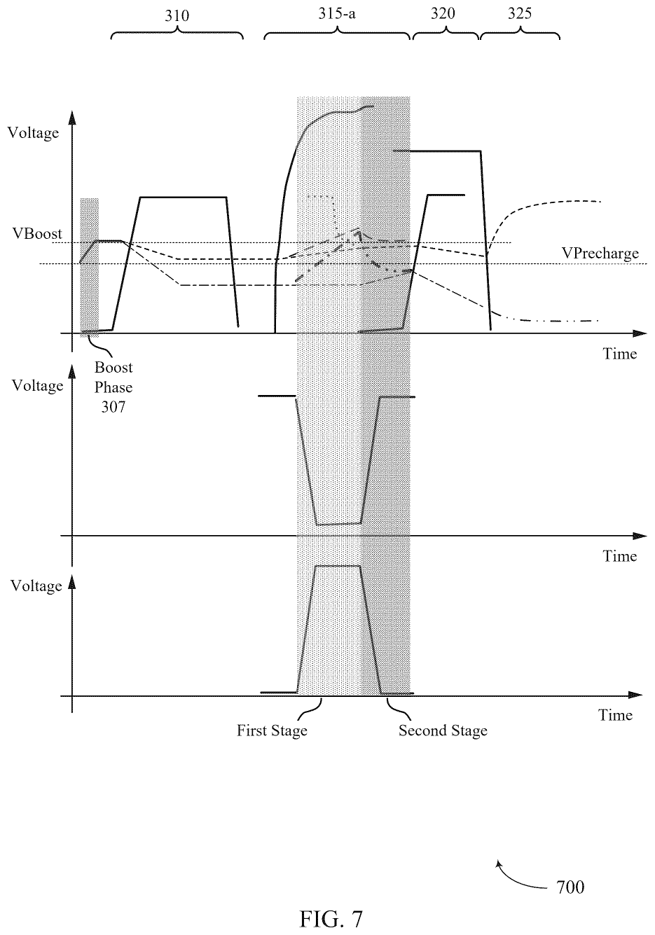

During the precharge phase 305, the digit lines of the sense amplifier 300 may be precharged to a precharge level (e.g., VPrecharge). Additional details regarding the precharge phase 305 are described with reference to FIGS. 6 and 7.

During the compensation phase 310, the threshold voltages of transistor N1 and transistor N2 may be compensated. The threshold voltage of transistor N1 may be compensated by coupling node 3 with voltage supply Vnary (and closing transistor B1 and opening transistor I1) so that a voltage based on the threshold voltage of transistor N1 is developed on digit line DLb. For example, the voltage on DLb (e.g., the precharge level) may be reduced by an amount that is based on (e.g., equal to) the threshold voltage of transistor N1. The threshold voltage of transistor N2 may be compensated by coupling node 3 with voltage supply Vnary (and closing transistor B2 and opening transistor I2) so that a voltage based on the threshold voltage of transistor N2 is developed on digit line DLa. For example, the voltage on DLa (e.g., the precharge level) may be reduced by an amount that is based on (e.g., equal to) the threshold voltage of transistor N2. Developing voltages on the digit lines that are based on the threshold voltages of transistor N1 and transistor N2 may allow the sense amplifier to counteract the impact of the threshold voltages of transistor N1 and transistor N2 during the amplification phase 320.

During the sensing phase 315 (which may also be referred to as the development phase), a voltage representative of (e.g., based on) the logic state stored by memory cell A may be developed on digit line DLa. For example, memory cell A may be coupled with digit line DLa (e.g., by activating the word line coupled with memory cell A, closing transistor I1, and opening transistor B1) so that memory cell A charge-shares with digit line DLa. Thus, the voltage on digit line DLa after the sensing phase 315 may be representative of (e.g., based on) the logic state stored by memory cell A. During the sensing phase 315, the voltage on digit line DLb may be maintained (e.g., at the compensated level from the compensation phase 310).

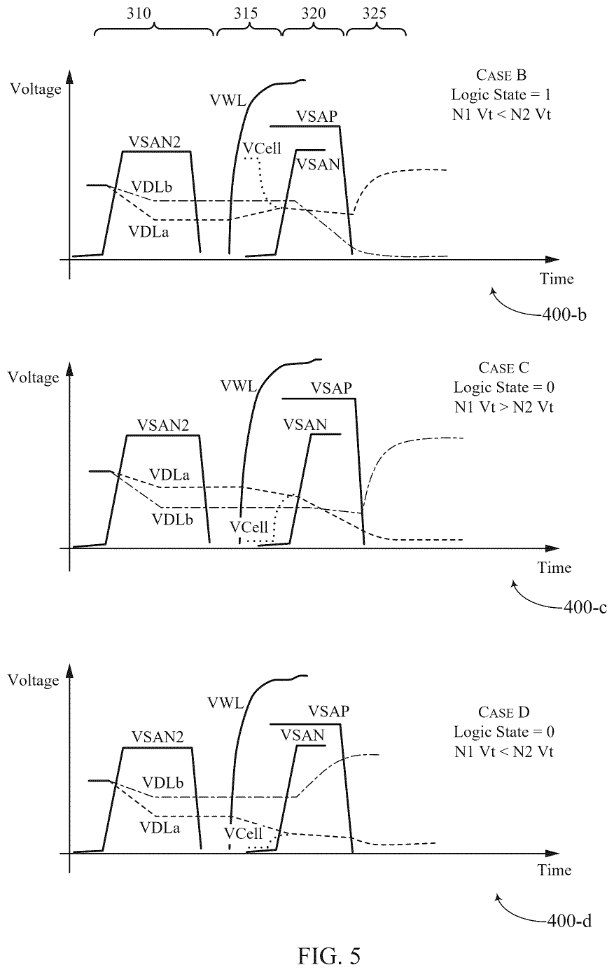

During the amplification phase 320, the voltage differential between the digit lines may be amplified and, in some cases (e.g., in case B and case C as illustrated in FIG. 5) inverted. Put another way, the magnitude of the voltage difference between digit line DLa and digit line DLb may be amplified and, in some cases in (e.g., in case B and case C as illustrated in FIG. 5) the polarity of the voltage difference may be inverted. The amplification phase 320 may include coupling transistor N1 and transistor N2 with voltage supply Vss (e.g., by closing switching component SAN while switching component SAN2 in open). During the amplification phase 320, the impact of the threshold voltages of transistor N1 and transistor N2 may be offset due to the compensation from the compensation phase 310.

During the latching phase 325, the voltages on the digit lines may be latched at the sense amplifier 300. For example, transistor P1 and transistor P2 may be coupled with voltage supply Vary (e.g., by closing switching component SAP) so that the voltages on the digit lines are latched on node 1 and node 2, respectively. In some examples, switching component I1 and switching component I2 may be closed (and switching component B1 and switching component B2 may be open) during the latching phase 325 so that memory cell A can be re-written with the logic state. Alternatively, each of the switching components I1, B1, I2, and B2 may be open.

Thus, during a sense operation, the sense amplifier 300 may be operated so that the transistors (e.g., transistor N1 and transistor N2) compensated for during the compensation phase are the same transistors used for amplification during the amplification phase, which may reduce or eliminate compensation mismatch. Such a technique may be enabled by coupling node 3 with voltage supply Vnary during the compensation phase and coupling node 3 with volage supply Vss during the amplification phase.

FIG. 4 shows an example of a timing diagram 400 that supports threshold voltage compensation for a memory system sense amplifier in accordance with examples as disclosed herein. The timing diagram 400 may represent the voltages of various nodes of the sense amplifier 300 during a sense operation for memory cell A in which memory cell A stores a logic 1 and in which the threshold voltage of transistor N1 is greater than the threshold voltage of transistor N2 (case A). The voltage on digit line DLa may be denoted VDLa and the voltage on digit line DL b may be denoted VDLb. The voltage applied to the gate terminal of transistor SAN may be denoted VSAN, the voltage applied to the gate terminal of transistor SAN2 may be denoted VSAN2, and the voltage applied to transistor SAP may be denoted VSAP. The voltage of memory cell A may be denoted VCell, and the voltage applied to the word line coupled with memory cell A may be denoted VWL.

The sense operation for memory cell A may include a compensation phase 310, a sensing phase 315, an amplification phase 320, and a latching phase 325, which may be examples of corresponding phases described with reference to FIG. 3. In some examples, a precharge phase, in which the digit lines are precharged to a precharge level (e.g., VPrecharge) may precede the compensation phase 310. During the compensation phase 310, the threshold voltages of transistor N1 and transistor N2 may be compensated. During the sensing phase 315, memory cell A may charge-share with digit line DLa. During the amplification phase 330, the voltage differential (which may represent the stored logic state of memory cell A) between digit line DLa and DLb may be amplified and potentially inverted. During the latching phase 325, the voltages on the digit lines may be latched at the sense amplifier 300.

Before the compensation phase 310 (e.g., during precharge phase 305), digit line DLa and digit line DLb may be precharged to a precharge level (e.g., VPrecharge). Node 1 and node 2 may also be precharged to the precharge level (e.g., due to switching components I1 and I2 being closed).

During the compensation phase 310, the threshold voltages of transistor N1 and transistor N2 may be compensated. For example, node 3 (and thus transistor N1 and transistor N2) may be coupled with voltage supply Vnary so that the voltages on the digit lines are reduced by the threshold voltages of transistor N1 and transistor N2 (e.g., due to the transistors being in a diode configuration). For instance, the voltage on digit line DLa may decrease by an amount that is based on (e.g., equal to) the threshold voltage of transistor N2 and the voltage on digit line DLb may decrease by an amount that is based on (e.g., equal to) the threshold voltage of transistor N1. Developing voltages on the digit lines that are based on the threshold voltages of transistor N1 and transistor N2 may allow the sense amplifier to counteract the impact of the threshold voltages of transistor N1 and transistor N2 during the amplification phase 320.

During the compensation phase 310, switching components B1 and B2 may be closed (e.g., to couple node 1 and node 2 with respective gate terminals and digit lines) and switching components I1 and I2 may be open (e.g., to isolate node 1 and node 2 from respective digit lines). Node 3 may be coupled with voltage supply Vnary (e.g., at time t1) by increasing VSAN2 and may be isolated from voltage supply Vnary (e.g., before the sensing phase 315) by decreasing VSAN2.

During the sensing phase 315, memory cell A may charge-share with digit line DLa. For example, memory cell A may be coupled with digit line DLa (e.g., by activating the word line) so that memory cell A charge-shares with digit line DLa. In the given example, charge-sharing between memory cell A and digit line DLa may increase the voltage on digit line DLa (e.g., due to memory cell A storing a logic 1) and generate a voltage difference, VDiff0, between the digit lines at time t2. During the sensing phase 315, switching components B1 and B2 may be open (e.g., to isolate node 1 and node 2 from respective gate terminals and digit lines) and switching components I1 and I2 may be closed (e.g., to couple node 1 and node 2 with respective digit lines).

During the amplification phase 320, the voltage differential (which may represent the stored logic state of memory cell A) between digit line DLa and DLb may be amplified. For example, node 3 (and thus transistor N1 and transistor N2) may be coupled with voltage supply Vss so that the voltage difference between digit line DLa and DLb is increased to Vdiff1 at time t3. Vdiff1 may represent the logic state of memory cell A. Thus, amplification may be performed by the same transistors (e.g., transistor N1 and N2) that were compensated during compensation phase 310, which may reduce or eliminate compensation mismatch. During the amplification phase 320, switching components B1 and B2 may be open (e.g., to isolate node 1 and node 2 from respective gate terminals and digit lines) and switching components I1 and I2 may be closed (e.g., to couple node 1 and node 2 with respective digit lines).

During the latching phase 325, the voltages on the digit lines may be latched at the sense amplifier 300. For example, the voltage on digit line DLa may be latched at node 1 and the voltage on digit line DLb may be latched at node 2 by coupling transistor P1 and transistor P2 with voltage supply Vary. Transistor P1 and transistor P2 may be coupled with voltage supply Vary by increasing VSAP so that transistor SAP is closed. During the latching phase 325, in a first example, switching components B1 and B2 may be open (e.g., to isolate node 1 and node 2 from respective gate terminals and digit lines) and switching components I1 and I2 may be closed (e.g., to couple node 1 and node 2 with respective digit lines) so that memory cell A can be re-written with the logic state. During the latching phase 325, in a second example, switching components B1 and B2 may be open and switching components I1 and I2 may be open.

Thus, the sense amplifier 300 may be operated so that the transistors (e.g., transistor N1 and N2) used for amplification during the amplification phase 320 are the same transistors that were compensated during the compensation phase 310, which may reduce or eliminate compensation mismatch.

FIG. 5 shows examples of timing diagrams 400 that support threshold voltage compensation for a memory system sense amplifier in accordance with examples as disclosed herein. The timing diagrams 400 may represent alternative voltages of various nodes of the sense amplifier 300 during a sense operation for memory cell A. For example, the timing diagrams 400 may include: timing diagram 400-b for case B, in which memory cell A stores a logic 1 and in which the threshold voltage of transistor N1 is less than the threshold voltage of transistor N2; timing diagram 400-c for case C, in which memory cell A stores a logic 0 and in which the threshold voltage of transistor N1 is greater than the threshold voltage of transistor N2; and timing diagram 400-d for case D, in which memory cell A stores a logic 0 and in which the threshold voltage of transistor N1 is less than the threshold voltage of transistor N2.

The general operation of the sense amplifier 300 may be similar across the different cases. However, the voltages of various nodes may be different across the different cases as described below.

Referring to case B, during the compensation phase 310 the voltage on digit line of DLa may be decreased (e.g., from the precharge level) by a greater amount than the voltage on digit line DLb (e.g., due to the threshold voltage of transistor N2 being greater than the threshold voltage of transistor N1). During the sensing phase 315, charge-sharing between memory cell A and digit line DLa may increase the voltage on digit line DLa (e.g., due to memory cell A storing a logic 1). During the amplification phase 320, the magnitude of the voltage difference between digit line DLa and digit line DLb may be increased, and the polarity of the voltage difference may be inverted (e.g., VDLb may be pulled lower than VDLa to indicate that memory cell A stored a logic 1).

Referring to case C, during the compensation phase 310 the voltage on digit line of DLa may be decreased (e.g., from the precharge level) by a lesser amount than the voltage on digit line DLb (e.g., due to the threshold voltage of transistor N1 being greater than the threshold voltage of transistor N2). During the sensing phase 315, charge-sharing between memory cell A and digit line DL a may decrease the voltage on digit line DLa (e.g., due to memory cell A storing a logic 0). During the amplification phase 320, the magnitude of the voltage difference between digit line DLa and digit line DLb may be increased, and the polarity of the voltage difference may be inverted (e.g., VDLa may be pulled lower than VDLb to indicate that memory cell A stored a logic 0).

Referring to case D, during the compensation phase 310 the voltage on digit line of DLa may be decreased (e.g., from the precharge level) by a greater amount than the voltage on digit line DLb (e.g., due to the threshold voltage of transistor N2 being greater than the threshold voltage of transistor N1). During the sensing phase 315, charge-sharing between memory cell A and digit line DLa may decrease the voltage on digit line DLa (e.g., due to memory cell A storing a logic 0). During the amplification phase 320, the magnitude of the voltage difference between digit line DLa and digit line DLb may be increased.

FIG. 6 shows an example of a sense amplifier 300-b that supports threshold voltage compensation in accordance with examples as disclosed herein. The sense amplifier 300-b may be an example of the sense amplifier 300 with additional components: switching component D1, switching component D2, switching component EQ, and voltage supply V2. The additional components may enable a boost phase 307 for the sense amplifier 300-b and may enable boosting of the voltages on node 1 and node 2 during the sensing phase 315-a. The other phases of the sense operation (e.g., precharge phase 305, compensation phase 310, amplification phase 320, and latching phase 325) may be the same as described with reference to FIG. 3.

During the boost phase 307, the voltages on the digit lines may be increased from the precharge level (e.g., VPrecharge) to a boosted level (e.g., VBoost) so that the difference between the voltages outputted by voltage supply Vss and voltage supply Vnary can be smaller relative to other techniques. During the sensing phase 315-a, the voltages on node 1 and node 2 may be increased so that the read window (e.g., the voltage difference between digit line DLa and digit line DLb) is more centered around VBoost, which may improve the reliability of the sensing operation.

Switching component EQ may be configured to selectively couple voltage supply V2 with node 4 and node 5. Switching component D1 may be configured to selectively couple digit line DLa with node 4. Switching component D2 may be configured to selectively couple digit line DLb with node 5. In some examples, switching component EQ is a p-type transistor and switching components D1 and D2 are n-type transistors.

Before the boost phase 307, the digit lines may be precharged to a precharge level (e.g., VPrecharge). For example, digit line DLa may be precharged to VPrecharge and digit line DLb may be precharged to VPrecharge.

During the boost phase 307, the voltage on the digit lines may be increased from VPrecharge to VBoost by coupling the digit lines with voltage supply V2. For example, digit line DLa may charge to VBoost and digit line DLb may charge to VBoost based on (e.g., in response to) closing switching components EQ, D1, and D2. During the boost phase 307, switching components I1 and I2 may be closed (e.g., so that node 1 and node 2 also charge to VBoost) and switching components B1 and B2 may be open. Thus, after boost phase 307, digit line DLa, digit line DLb, node 1, and node 2 may be charged to VBoost.

Sensing phase 315-a may be divided into stage 1 and stage 2. During stage 1 of sensing phase 315-a: the voltages on node 1 and node 2 may be increased from the compensated levels (e.g., by closing switching components EQ, I1, and I2 so that voltage supply V2 is coupled with node 1 and node 2); and memory cell A may charge-share with digit line DLa (e.g., by activating the word line). During stage 1, the digit lines may be isolated from node 1 and node 2 by opening switching components D1 and D2. During stage 2 of sensing phase 315-a, the digit lines may charge-share with node 1 and node 2 (e.g., by closing switching components D1, D2, I1, and I2 so that the digit lines are coupled with node 1 and node 2). Thus, after sensing phase 315-a, the voltages on node 1 and node 2 may be increased relative to other techniques so that the read window (e.g., the voltage difference between digit line DLa and digit line DLb) is more centered around VBoost, which may improve the reliability of the sensing operation.

Thus, the additional components may enable the boost phase 307 for the sense amplifier 300-b as well as the boosting of the voltages on node 1 and node 2 during the sensing phase 315-a.

FIG. 7 shows an example of a timing diagram 700 that supports threshold voltage compensation for a memory system sense amplifier in accordance with examples as disclosed herein. The timing diagram 700 may represent the voltages of various nodes of the sense amplifier 300-b during a sense operation for memory cell A in which memory cell A stores a logic 1 and in which the threshold voltage of transistor N1 is greater than the threshold voltage of transistor N2 (case A). The voltage on digit line DLa may be denoted VDLa and the voltage on digit line DL b may be denoted VDLb. The voltage applied to the gate terminal of transistor SAN may be denoted VSAN, the voltage applied to the gate terminal of transistor SAN2 may be denoted VSAN2, and the voltage applied to transistor SAP may be denoted VSAP. The voltage of memory cell A may be denoted VCell, and the voltage applied to the word line coupled with memory cell A may be denoted VWL.

Timing diagram 700 may be similar to timing diagram 400. However, timing diagram 700 may include boost phase 307 and a multi-stage sensing phase 315-a. During the boost phase 307, the voltages on the digit lines (and node 1 and node 2) may be increased from VPrecharge to VBoost. During the first stage of sensing phase 315-a, 1) the voltages on node 1 and node 2 may be increased, and 2) memory cell A may charge-charge with digit line DLa. During the second stage of sensing phase 315-a, the digit lines may charge-share with the node 1 and node 2.

During the precharge phase 305, digit line DLa and digit line DLb may be precharged to a precharge level (e.g., VPrecharge). Node 1 and node 2 may also be precharged to the precharge level (e.g. by closing switching components D1, D2, I1, and I2).

During boost phase 307, the voltages on digit line DLa and digit line DLb (and node 1 and node 2) may be increased from VPrecharge to VBoost. To do so, the digit lines may be coupled with voltage supply V2 (e.g., by closing switching components EQ, D1, and D2); and node 1 and node 2 may be coupled with voltage supply V2 (e.g., by closing switching components EQ, I1, and I2). Among other advantages, increasing the pre-compensation voltage on the digit lines and nodes to VBoost may allow use of a lower voltage supply Vnary relative to other techniques, which may reduce power consumption by the sense amplifier 300.

During the compensation phase 310, the threshold voltages of transistor N1 and transistor N2 may be compensated as described herein and with reference to FIG. 4.

During the first stage of sensing phase 315-a, memory cell A may charge-share with digit line DLa. For example, memory cell A may be coupled with digit line DLa (e.g., by activating the word line) so that memory cell A charge-shares with digit line DLa. Also, during the first stage of sensing phase 315-a, the voltages on node 1 and node 2 may be increased (e.g., from compensated levels to a level greater than VBoost) by coupling node 1 and node 2 with voltage supply V2. Increasing the voltages on node 1 and node 2 may allow the read window (e.g., the voltage difference between digit line DL a and digit line DLb) to be positioned around VBoost after the second stage of sensing phase 315-a, which may improve the reliability of the sensing operation. During the first stage of sensing phase 315-a: switching components D1 and D2 may be open so that the digit lines are isolated from node 1 and node 2; switching components I1, I2, and EQ maybe closed so that node 1 and node 2 are coupled with voltage supply V2; and switching components B1 and B2 may be open.

During the second stage of sensing phase 315-a, the digit lines may charge-share with node 1 and node 2. For example, digit line DLa may charge-share with node 1 whereas digit line DLb may charge-share with node 2. Digit line DLa may charge-share with node 1 by coupling digit line DLa with node 1 (e.g., by closing switching components D1 and I1). Similarly, digit line DLb may charge-share with node 2 by coupling digit line DLb with node 2 (e.g., by closing switching components D2 and I2). During the second stage of sensing phase 315-a, switching component EQ may be open to isolate voltage supply V2.

During amplification phase 320, the voltage differential (which may represent the stored logic state of memory cell A) between digit line DLa and DLb may be amplified as described herein and with reference to FIG. 4. During the latching phase 325, the voltages on the digit lines may be latched at the sense amplifier 300 as described herein and with reference to FIG. 4.

Thus, the sense amplifier 300-b may be operated so that a sense operation includes a boost phase 307 and a multi-stage sensing phase 315-a.

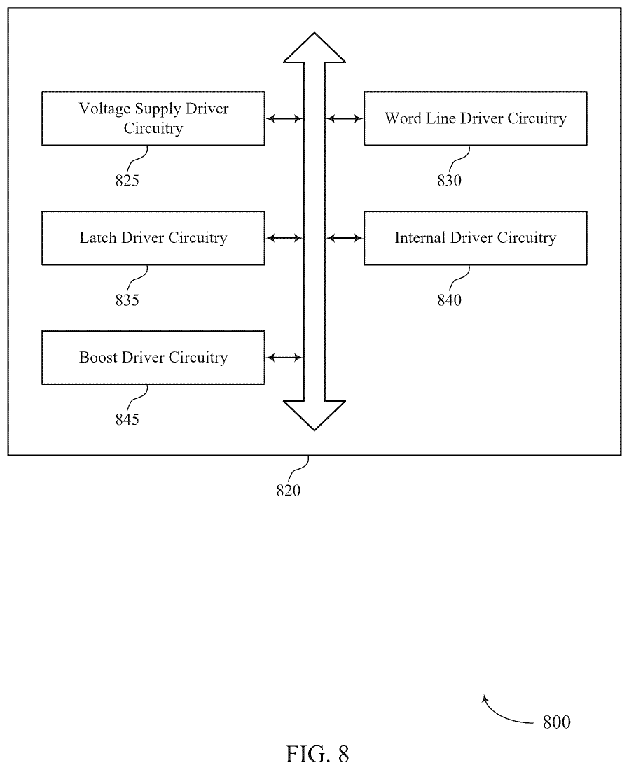

FIG. 8 shows a block diagram 800 of a memory system 820 that supports threshold voltage compensation for a memory system sense amplifier in accordance with examples as disclosed herein. The memory system 820 may be an example of aspects of a memory system as described with reference to FIGS. 1 through 7. The memory system 820, or various components thereof, may be an example of means for performing various aspects of threshold voltage compensation for a memory system sense amplifier as described herein. For example, the memory system 820 may include a voltage supply driver circuitry 825, a word line driver circuitry 830, a latch driver circuitry 835, an internal driver circuitry 840, a boost driver circuitry 845, or any combination thereof. Each of these components, or components of subcomponents thereof (e.g., one or more processors, one or more memories), may communicate, directly or indirectly, with one another (e.g., via one or more buses).

The voltage supply driver circuitry 825 may be configured as or otherwise support a means for coupling a first voltage supply with a source terminal of a first transistor and with a source terminal of a second transistor, where coupling the first voltage supply compensates for a first threshold voltage of the first transistor and a second threshold voltage of the second transistor. The word line driver circuitry 830 may be configured as or otherwise support a means for coupling, after coupling the first voltage supply with the source terminal of the first transistor and with the source terminal of the second transistor, a memory cell with a first digit line, where the memory cell charge-shares with the first digit line based at least in part on coupling the memory cell with the first digit line. In some examples, the voltage supply driver circuitry 825 may be configured as or otherwise support a means for coupling a second voltage supply with the source terminal of the first transistor and with the source terminal of the second transistor after coupling the memory cell with the first digit line, where coupling the second voltage supply causes the first transistor and the second transistor to amplify a voltage difference between the first digit line and a second digit line, the voltage difference representative of a stored logic state of the memory cell.

In some examples, the voltage difference is between a first voltage on the first digit line and a second voltage on the second digit line, and the latch driver circuitry 835 may be configured as or otherwise support a means for activating, based at least in part on coupling the second voltage supply with the source terminal of the first transistor and with the source terminal of the second transistor, a third transistor and a fourth transistor each coupled with the first transistor and the second transistor, where activating the third transistor and the fourth transistor latches the first voltage on the first digit line and the second voltage on the second digit line.

In some examples, the voltage supply driver circuitry 825 may be configured as or otherwise support a means for coupling a drain terminal of the first transistor with a third voltage supply based at least in part on coupling the memory cell with the first digit line. In some examples, the internal driver circuitry 840 may be configured as or otherwise support a means for coupling the first digit line with the drain terminal of the first transistor based at least in part on coupling the drain terminal of the first transistor with the third voltage supply, where the second voltage supply is coupled with the source terminal of the first transistor based at least in part on coupling the first digit line with the drain terminal of the first transistor.

In some examples, the voltage supply driver circuitry 825 may be configured as or otherwise support a means for coupling a drain terminal of the second transistor with the third voltage supply based at least in part on coupling the memory cell with the first digit line. In some examples, the internal driver circuitry 840 may be configured as or otherwise support a means for coupling the second digit line with the drain terminal of the second transistor based at least in part on coupling the drain terminal of the second transistor with the third voltage supply, where the second voltage supply is coupled with the source terminal of the second transistor based at least in part on coupling the second digit line with the drain terminal of the second transistor.

In some examples, the boost driver circuitry 845 may be configured as or otherwise support a means for coupling the first digit line with a third voltage supply after precharging the first digit line to a first voltage level and before coupling the first voltage supply with the source terminal of the first transistor, where the first digit line is charged to a second voltage level higher than the first voltage level based at least in part on coupling the first digit line with the third voltage supply.

In some examples, the boost driver circuitry 845 may be configured as or otherwise support a means for coupling the second digit line with the third voltage supply after precharging the second digit line to the first voltage level and before coupling the first voltage supply with the source terminal of the second transistor, where the second digit line is charged to the second voltage level based at least in part on coupling the second digit line with the third voltage supply.

In some examples, the internal driver circuitry 840 may be configured as or otherwise support a means for coupling a drain terminal of the first transistor with a gate terminal of the first transistor and with the second digit line, where the first voltage supply is coupled with the source terminal of the first transistor based at least in part on coupling the drain terminal of the first transistor with the gate terminal of the first transistor and with the second digit line. In some examples, the internal driver circuitry 840 may be configured as or otherwise support a means for isolating the drain terminal of the first transistor from the first digit line, where the first voltage supply is coupled with the source terminal of the first transistor based at least in part on isolating drain terminal of the first transistor from the first digit line.

In some examples, the internal driver circuitry 840 may be configured as or otherwise support a means for coupling a drain terminal of the second transistor with a gate terminal of the second transistor and with the first digit line, where the first voltage supply is coupled with the source terminal of the second transistor based at least in part on coupling the drain terminal of the second transistor with the gate terminal of the second transistor and with the first digit line. In some examples, the internal driver circuitry 840 may be configured as or otherwise support a means for isolating the drain terminal of the second transistor from the second digit line, where the first voltage supply is coupled with the source terminal of the second transistor based at least in part on isolating drain terminal of the second transistor from the second digit line.

In some examples, the described functionality of the memory system 820, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 820, or various components thereof, may be implemented at least in part by instructions (e.g., stored in memory, non-transitory computer-readable medium) executable by such at least one processor.

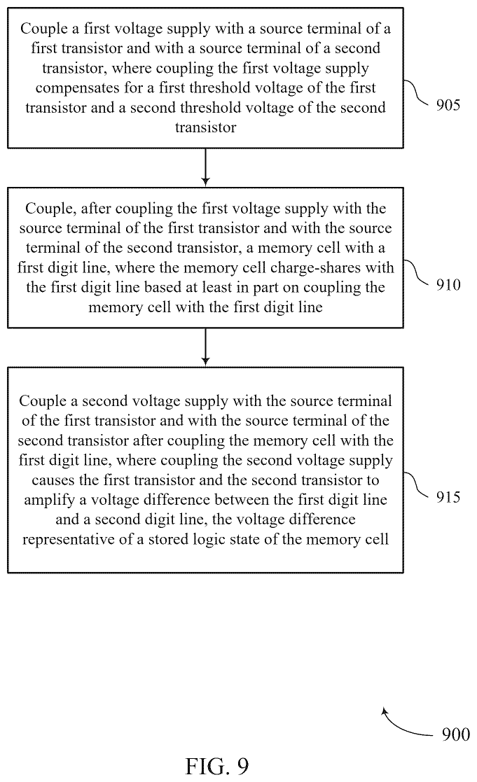

FIG. 9 shows a flowchart illustrating a method 900 that supports threshold voltage compensation for a memory system sense amplifier in accordance with examples as disclosed herein. The operations of method 900 may be implemented by a memory system or its components as described herein. For example, the operations of method 900 may be performed by a memory system as described with reference to FIGS. 1 through 8. In some examples, a memory system may execute a set of instructions to control the functional elements of the device to perform the described functions. Additionally, or alternatively, the memory system may perform aspects of the described functions using special-purpose hardware.

At 905, the method may include coupling a first voltage supply with a source terminal of a first transistor and with a source terminal of a second transistor, where coupling the first voltage supply compensates for a first threshold voltage of the first transistor and a second threshold voltage of the second transistor. In some examples, aspects of the operations of 905 may be performed by a voltage supply driver circuitry 825 as described with reference to FIG. 8.

At 910, the method may include coupling, after coupling the first voltage supply with the source terminal of the first transistor and with the source terminal of the second transistor, a memory cell with a first digit line, where the memory cell charge-shares with the first digit line based at least in part on coupling the memory cell with the first digit line. In some examples, aspects of the operations of 910 may be performed by a word line driver circuitry 830 as described with reference to FIG. 8.

At 915, the method may include coupling a second voltage supply with the source terminal of the first transistor and with the source terminal of the second transistor after coupling the memory cell with the first digit line, where coupling the second voltage supply causes the first transistor and the second transistor to amplify a voltage difference between the first digit line and a second digit line, the voltage difference representative of a stored logic state of the memory cell. In some examples, aspects of the operations of 915 may be performed by a voltage supply driver circuitry 825 as described with reference to FIG. 8.

In some examples, an apparatus as described herein may perform a method or methods, such as the method 900. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for coupling a first voltage supply with a source terminal of a first transistor and with a source terminal of a second transistor, where coupling the first voltage supply compensates for a first threshold voltage of the first transistor and a second threshold voltage of the second transistor; coupling, after coupling the first voltage supply with the source terminal of the first transistor and with the source terminal of the second transistor, a memory cell with a first digit line, where the memory cell charge-shares with the first digit line based at least in part on coupling the memory cell with the first digit line; and coupling a second voltage supply with the source terminal of the first transistor and with the source terminal of the second transistor after coupling the memory cell with the first digit line, where coupling the second voltage supply causes the first transistor and the second transistor to amplify a voltage difference between the first digit line and a second digit line, the voltage difference representative of a stored logic state of the memory cell.

Aspect 2: The method, apparatus, or non-transitory computer-readable medium of aspect 1, where the voltage difference is between a first voltage on the first digit line and a second voltage on the second digit line and the method, apparatuses, and non-transitory computer-readable medium further includes operations, features, circuitry, logic, means, or instructions, or any combination thereof for activating, based at least in part on coupling the second voltage supply with the source terminal of the first transistor and with the source terminal of the second transistor, a third transistor and a fourth transistor each coupled with the first transistor and the second transistor, where activating the third transistor and the fourth transistor latches the first voltage on the first digit line and the second voltage on the second digit line.

Aspect 3: The method, apparatus, or non-transitory computer-readable medium of any of aspects 1 through 2, further including operations, features, circuitry, logic, means, or instructions, or any combination thereof for coupling a drain terminal of the first transistor with a third voltage supply based at least in part on coupling the memory cell with the first digit line and coupling the first digit line with the drain terminal of the first transistor based at least in part on coupling the drain terminal of the first transistor with the third voltage supply, where the second voltage supply is coupled with the source terminal of the first transistor based at least in part on coupling the first digit line with the drain terminal of the first transistor.

Aspect 4: The method, apparatus, or non-transitory computer-readable medium of aspect 3, further including operations, features, circuitry, logic, means, or instructions, or any combination thereof for coupling a drain terminal of the second transistor with the third voltage supply based at least in part on coupling the memory cell with the first digit line and coupling the second digit line with the drain terminal of the second transistor based at least in part on coupling the drain terminal of the second transistor with the third voltage supply, where the second voltage supply is coupled with the source terminal of the second transistor based at least in part on coupling the second digit line with the drain terminal of the second transistor.

Aspect 5: The method, apparatus, or non-transitory computer-readable medium of any of aspects 1 through 4, further including operations, features, circuitry, logic, means, or instructions, or any combination thereof for coupling the first digit line with a third voltage supply after precharging the first digit line to a first voltage level and before coupling the first voltage supply with the source terminal of the first transistor, where the first digit line is charged to a second voltage level higher than the first voltage level based at least in part on coupling the first digit line with the third voltage supply.

Aspect 6: The method, apparatus, or non-transitory computer-readable medium of aspect 5, further including operations, features, circuitry, logic, means, or instructions, or any combination thereof for coupling the second digit line with the third voltage supply after precharging the second digit line to the first voltage level and before coupling the first voltage supply with the source terminal of the second transistor, where the second digit line is charged to the second voltage level based at least in part on coupling the second digit line with the third voltage supply.

Aspect 7: The method, apparatus, or non-transitory computer-readable medium of any of aspects 1 through 6, further including operations, features, circuitry, logic, means, or instructions, or any combination thereof for coupling a drain terminal of the first transistor with a gate terminal of the first transistor and with the second digit line, where the first voltage supply is coupled with the source terminal of the first transistor based at least in part on coupling the drain terminal of the first transistor with the gate terminal of the first transistor and with the second digit line and isolating the drain terminal of the first transistor from the first digit line, where the first voltage supply is coupled with the source terminal of the first transistor based at least in part on isolating drain terminal of the first transistor from the first digit line.

Aspect 8: The method, apparatus, or non-transitory computer-readable medium of aspect 7, further including operations, features, circuitry, logic, means, or instructions, or any combination thereof for coupling a drain terminal of the second transistor with a gate terminal of the second transistor and with the first digit line, where the first voltage supply is coupled with the source terminal of the second transistor based at least in part on coupling the drain terminal of the second transistor with the gate terminal of the second transistor and with the first digit line and isolating the drain terminal of the second transistor from the second digit line, where the first voltage supply is coupled with the source terminal of the second transistor based at least in part on isolating drain terminal of the second transistor from the second digit line.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 9: An apparatus, including: a memory array including a memory cell coupled with a first digit line; and a sense amplifier coupled with the first digit line and including: a first transistor including: a gate terminal coupled with a second digit line, a drain terminal coupled with the first digit line through a first switching component, and a source terminal coupled with a node; a second transistor including: a gate terminal coupled with the first digit line, a drain terminal coupled with the first digit line through a second switching component, and a source terminal coupled with the node; a first voltage supply configured to be coupled with the node using a third transistor during an amplification phase of a sense operation for the memory cell; and a second voltage supply configured to be coupled with the node through a fourth transistor during a compensation phase of the sense operation.

Aspect 10: The apparatus of aspect 9, further including: one or more drivers configured to: activate, for a first duration, the fourth transistor to couple the second voltage supply with the node; and activate, for a second duration after the first duration, the third transistor to couple the first voltage supply with the node.

Aspect 11: The apparatus of any of aspects 9 through 10, further including: one or more drivers configured to activate, during the compensation phase of the sense operation, the fourth transistor to couple the second voltage supply with the node, where the compensation phase compensates for a first threshold voltage of the first transistor and a second threshold voltage of the second transistor.

Aspect 12: The apparatus of aspect 11, where the one or more drivers is configured to activate, after the compensation phase and during the amplification phase of the sense operation, the third transistor to couple the first voltage supply with the node, the amplification phase amplifies a voltage difference between the first digit line and the second digit line.

Aspect 13: The apparatus of aspect 12, where the second voltage supply supplies a higher voltage level than the first voltage supply.

Aspect 14: The apparatus of any of aspects 9 through 13, further including: a third switching component configured to selectively couple a third voltage supply with the first digit line and the second digit line during a sensing phase of the sense operation; a fourth switching component configured to selectively couple the first switching component with the first digit line; and a fifth switching component configured to selectively couple the second switching component with second digit line.

Aspect 15: The apparatus of aspect 14, further including: one or more drivers configured to: deactivate, after coupling the first digit line with the memory cell, the fourth switching component and the fifth switching component; and activate, after coupling the first digit line with the memory cell, the third switching component.

Aspect 16: The apparatus of any of aspects 14 through 15, further including: one or more drivers configured to: activate the fourth switching component after precharging the first digit line to a first voltage level, where the first digit line is charged to a second voltage level higher than the first voltage level based at least in part on activating the fourth switching component; and activate the fifth switching component after precharging the second digit line to the first voltage level, where the first digit line is charged to the second voltage level based at least in part on activating the fifth switching component.

Aspect 17: The apparatus of any of aspects 9 through 16, further including: a third switching component configured to selectively couple the drain terminal of the first transistor with the gate terminal of the first transistor and with the second digit line; and a fourth switching component configured to selectively couple the drain terminal of the second transistor with the gate terminal of the second transistor and with the first digit line.

An apparatus is described. The following provides an overview of aspects of the apparatus as described herein:

Aspect 18: A memory device, including: a sense amplifier coupled with a first digit line and a second digit line; and one or more controllers coupled with the sense amplifier and configured to cause the memory device to: couple a first voltage supply with a source terminal of a first transistor and with a source terminal of a second transistor, where coupling the first voltage supply compensates for a first threshold voltage of the first transistor and a second threshold voltage of the second transistor; couple, after coupling the first voltage supply with the source terminal of the first transistor and with the source terminal of the second transistor, a memory cell with the first digit line, where the memory cell charge-shares with the first digit line based at least in part on coupling the memory cell with the first digit line; and couple a second voltage supply with the source terminal of the first transistor and with the source terminal of the second transistor after coupling the memory cell with the first digit line, where coupling the second voltage supply causes the first transistor and the second transistor to amplify a voltage difference between the first digit line and a second digit line, the voltage difference representative of a stored logic state of the memory cell.

Aspect 19: The memory device of aspect 18, where the one or more controllers is further configured to cause the memory device to: couple a drain terminal of the first transistor with a third voltage supply based at least in part on coupling the memory cell with the first digit line; and couple the first digit line with the drain terminal of the first transistor based at least in part on coupling the drain terminal of the first transistor with the third voltage supply, where the second voltage supply is coupled with the source terminal of the first transistor based at least in part on coupling the first digit line with the drain terminal of the first transistor.

Aspect 20: The memory device of any of aspects 18 through 19, where the one or more controllers is further configured to cause the memory device to: couple the first digit line with a third voltage supply after precharging the first digit line to a first voltage level and before coupling the first voltage supply with the source terminal of the first transistor, where the first digit line is charged to a second voltage level higher than the first voltage level based at least in part on coupling the first digit line with the third voltage supply.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a memory array comprising a memory cell coupled with a first digit line; and
a sense amplifier coupled with the first digit line and comprising:
a first transistor comprising: a gate terminal coupled with a second digit line, a drain terminal coupled with the first digit line through a first switching component, and a source terminal coupled with a node;
a second transistor comprising: a gate terminal coupled with the first digit line, a drain terminal coupled with the first digit line through a second switching component, and a source terminal coupled with the node;
a first voltage supply configured to be coupled with the node using a third transistor during an amplification phase of a sense operation for the memory cell; and
a second voltage supply configured to be coupled with the node through a fourth transistor during a compensation phase of the sense operation.

2. The apparatus of claim 1, further comprising:
one or more drivers configured to:
activate, for a first duration, the fourth transistor to couple the second voltage supply with the node; and
activate, for a second duration after the first duration, the third transistor to couple the first voltage supply with the node.

3. The apparatus of claim 1, further comprising:
one or more drivers configured to activate, during the compensation phase of the sense operation, the fourth transistor to couple the second voltage supply with the node, wherein the compensation phase compensates for a first threshold voltage of the first transistor and a second threshold voltage of the second transistor.

4. The apparatus of claim 3, wherein:
the one or more drivers is configured to activate, after the compensation phase and during the amplification phase of the sense operation, the third transistor to couple the first voltage supply with the node,
the amplification phase amplifies a voltage difference between the first digit line and the second digit line.

5. The apparatus of claim 4, wherein the second voltage supply supplies a higher voltage level than the first voltage supply.

6. The apparatus of claim 1, further comprising:
a third switching component configured to selectively couple a third voltage supply with the first digit line and the second digit line during a sensing phase of the sense operation;
a fourth switching component configured to selectively couple the first switching component with the first digit line; and
a fifth switching component configured to selectively couple the second switching component with second digit line.

7. The apparatus of claim 6, further comprising:
one or more drivers configured to:
deactivate, after coupling the first digit line with the memory cell, the fourth switching component and the fifth switching component; and
activate, after coupling the first digit line with the memory cell, the third switching component.

8. The apparatus of claim 6, further comprising:
one or more drivers configured to:
activate the fourth switching component after precharging the first digit line to a first voltage level, wherein the first digit line is charged to a second voltage level higher than the first voltage level based at least in part on activating the fourth switching component; and
activate the fifth switching component after precharging the second digit line to the first voltage level, wherein the first digit line is charged to the second voltage level based at least in part on activating the fifth switching component.

9. The apparatus of claim 1, further comprising:
a third switching component configured to selectively couple the drain terminal of the first transistor with the gate terminal of the first transistor and with the second digit line; and
a fourth switching component configured to selectively couple the drain terminal of the second transistor with the gate terminal of the second transistor and with the first digit line.

10. A method for operating a sense amplifier of a memory device comprising:
coupling a first voltage supply with a source terminal of a first transistor and with a source terminal of a second transistor, wherein coupling the first voltage supply compensates for a first threshold voltage of the first transistor and a second threshold voltage of the second transistor;
coupling, after coupling the first voltage supply with the source terminal of the first transistor and with the source terminal of the second transistor, a memory cell with a first digit line, wherein the memory cell charge-shares with the first digit line based at least in part on coupling the memory cell with the first digit line; and
coupling a second voltage supply with the source terminal of the first transistor and with the source terminal of the second transistor after coupling the memory cell with the first digit line, wherein coupling the second voltage supply causes the first transistor and the second transistor to amplify a voltage difference between the first digit line and a second digit line, the voltage difference representative of a stored logic state of the memory cell.

11. The method of claim 10, wherein the voltage difference is between a first voltage on the first digit line and a second voltage on the second digit line, the method further comprising:
activating, based at least in part on coupling the second voltage supply with the source terminal of the first transistor and with the source terminal of the second transistor, a third transistor and a fourth transistor each coupled with the first transistor and the second transistor, wherein activating the third transistor and the fourth transistor latches the first voltage on the first digit line and the second voltage on the second digit line.

12. The method of claim 10, further comprising:
coupling a drain terminal of the first transistor with a third voltage supply based at least in part on coupling the memory cell with the first digit line; and
coupling the first digit line with the drain terminal of the first transistor based at least in part on coupling the drain terminal of the first transistor with the third voltage supply, wherein the second voltage supply is coupled with the source terminal of the first transistor based at least in part on coupling the first digit line with the drain terminal of the first transistor.

13. The method of claim 12, further comprising:
coupling a drain terminal of the second transistor with the third voltage supply based at least in part on coupling the memory cell with the first digit line; and
coupling the second digit line with the drain terminal of the second transistor based at least in part on coupling the drain terminal of the second transistor with the third voltage supply, wherein the second voltage supply is coupled with the source terminal of the second transistor based at least in part on coupling the second digit line with the drain terminal of the second transistor.

14. The method of claim 10, further comprising:
coupling the first digit line with a third voltage supply after precharging the first digit line to a first voltage level and before coupling the first voltage supply with the source terminal of the first transistor, wherein the first digit line is charged to a second voltage level higher than the first voltage level based at least in part on coupling the first digit line with the third voltage supply.

15. The method of claim 14, further comprising:
coupling the second digit line with the third voltage supply after precharging the second digit line to the first voltage level and before coupling the first voltage supply with the source terminal of the second transistor, wherein the second digit line is charged to the second voltage level based at least in part on coupling the second digit line with the third voltage supply.

16. The method of claim 10, further comprising:
coupling a drain terminal of the first transistor with a gate terminal of the first transistor and with the second digit line, wherein the first voltage supply is coupled with the source terminal of the first transistor based at least in part on coupling the drain terminal of the first transistor with the gate terminal of the first transistor and with the second digit line; and
isolating the drain terminal of the first transistor from the first digit line, wherein the first voltage supply is coupled with the source terminal of the first transistor based at least in part on isolating drain terminal of the first transistor from the first digit line.

17. The method of claim 16, further comprising:
coupling a drain terminal of the second transistor with a gate terminal of the second transistor and with the first digit line, wherein the first voltage supply is coupled with the source terminal of the second transistor based at least in part on coupling the drain terminal of the second transistor with the gate terminal of the second transistor and with the first digit line; and
isolating the drain terminal of the second transistor from the second digit line, wherein the first voltage supply is coupled with the source terminal of the second transistor based at least in part on isolating drain terminal of the second transistor from the second digit line.

18. A memory device, comprising:
a sense amplifier coupled with a first digit line and a second digit line; and
one or more controllers coupled with the sense amplifier and configured to cause the memory device to:
couple a first voltage supply with a source terminal of a first transistor and with a source terminal of a second transistor, wherein coupling the first voltage supply compensates for a first threshold voltage of the first transistor and a second threshold voltage of the second transistor;
couple, after coupling the first voltage supply with the source terminal of the first transistor and with the source terminal of the second transistor, a memory cell with the first digit line, wherein the memory cell charge-shares with the first digit line based at least in part on coupling the memory cell with the first digit line; and
couple a second voltage supply with the source terminal of the first transistor and with the source terminal of the second transistor after coupling the memory cell with the first digit line, wherein coupling the second voltage supply causes the first transistor and the second transistor to amplify a voltage difference between the first digit line and a second digit line, the voltage difference representative of a stored logic state of the memory cell.

19. The memory device of claim 18, wherein the one or more controllers is further configured to cause the memory device to:
couple a drain terminal of the first transistor with a third voltage supply based at least in part on coupling the memory cell with the first digit line; and
couple the first digit line with the drain terminal of the first transistor based at least in part on coupling the drain terminal of the first transistor with the third voltage supply, wherein the second voltage supply is coupled with the source terminal of the first transistor based at least in part on coupling the first digit line with the drain terminal of the first transistor.

20. The memory device of claim 18, wherein the one or more controllers is further configured to cause the memory device to:
couple the first digit line with a third voltage supply after precharging the first digit line to a first voltage level and before coupling the first voltage supply with the source terminal of the first transistor, wherein the first digit line is charged to a second voltage level higher than the first voltage level based at least in part on coupling the first digit line with the third voltage supply.
